(19) United States
(12) Patent Application Publication
(10) Pub. No.: US 2012/0286297 A1
(43) Pub. Date: Nov. 15, 2012

(54) LED PACKAGE STRUCTURE AND MODULE THEREOF

(75) Inventor: JIN SHEN WANG, TORRANCE, CA (US)

(73) Assignee: TAIWAN MICROPAQ CORPORATION, HSINCHU COUNTY (TW)

(21) Appl. No.: 13/103,225

(22) Filed: May 9, 2011

(51) Int. Cl. H01L 27/15; H01L 33/60; H01L 33/62

(52) U.S. Cl. 257/88; 257/99; 257/98; 257/E27.12; 257/E33.072; 257/E33.066

(57) ABSTRACT

The present invention discloses a LED package structure and a module thereof. The LED package structure comprises a metallic chip-carrying lead frame, a metallic anode lead frame, a metallic cathode lead frame and a forming resin. At least one LED chip is stuck to the metallic chip-carrying lead frame. The metallic anode lead frame and metallic cathode lead frame are arranged beside the metallic chip-carrying lead frame. The forming resin includes a top member, a first sidewall, and a second sidewall. The top member is arranged on the metallic chip-carrying lead frame and has an opening to reveal the LED chip. A reflective wall is formed along the opening. The first sidewall is arranged between the metallic chip-carrying lead frame and the metallic anode lead frame to join them. The second sidewall is arranged between the metallic chip-carrying lead frame and the metallic cathode lead frame to join them.

### BACKGROUND OF THE INVENTION

1. Field of the Invention

The present invention relates to a LED package structure and a module thereof, particularly to a LED package structure having separate paths to conduct light, electricity and heat and a module thereof

2. Description of the Related Art

A light emitting diode (LED) chip is joined to a substrate with a wire-bonding or flip-chip technology and then encapsulated to form a LED element. The LED element is soldered to a circuit board and electrically powered to function as a light source. In electricity-light conversion of LED, almost 80% energy is converted into heat. The power of a single LED chip has been gradually increased to 1-3 Watts recently and will be 5 or even 10 Watts in the future. In such a case, LED chip substrates and system circuit boards thereof should demand higher heat-radiating performance.

A LED package without appropriate heat-radiating design will gradually heat up, which will degrade light output efficiency, decrease brightness and change light color. It is a trend to use a ceramic substrate as the heat-radiating board in a high-power LED package. Refer to FIG. 1. The ceramic substrate 10 is made of aluminum oxide or aluminum nitride. Metal is deposited in the holes penetrating the ceramic substrate 10 to form metal film interconnections 12. The abovementioned design is adapted to high-power LED packages and superior in structural stability and circuitry accuracy. However, the high-thermal conductivity aluminum nitride (with a thermal conductivity of 240 W/mK) is more than 10 times expensive than the ordinary aluminum oxide (with a thermal conductivity of 25 W/mK) and hard to popularize in LED illumination.

Accordingly, the present invention proposes a LED package structure and a module thereof to overcome the utility and efficiency problems mentioned above.

### SUMMARY OF THE INVENTION

The primary objective of the present invention is to provide a LED package structure and a module thereof, wherein an advanced and precision press-molding technology of semiconductor package is used to construct a LED element having separate conduction paths of light, electricity and heat and a module thereof

Another objective of the present invention is to provide a LED package structure and a module thereof, which can effectively prevent LED chips from heating up in operation, increase the light efficiency of LED chips and prolong the service life of LED chips.

To achieve the abovementioned objectives, the present invention proposes a LED package structure, which comprises a metallic chip-carrying lead frame, a metallic anode lead frame and a metallic cathode lead frame, a forming resin and a plurality of leads. At least one LED chip is stuck to the metallic chip-carrying lead frame. The metallic anode lead frame and metallic cathode lead frame are arranged beside the metallic chip-carrying lead frame. The forming resin includes a top member, a first sidewall, and a second sidewall. The top member is arranged on the metallic chip-carrying lead frame and has an opening to reveal the LED chip. A reflective wall is formed along the opening. The first sidewall is arranged between the metallic chip-carrying lead frame and the metallic anode lead frame to join the metallic chip-carrying lead frame and the metallic anode lead frame. The second sidewall is arranged between the metallic chip-carrying lead frame and the metallic cathode lead frame to join the metallic chip-carrying lead frame and the metallic cathode lead frame. The leads electrically connect the LED chip with the metallic anode lead frame and the metallic cathode lead frame.

The present invention also proposes a LED module, which comprises a group of heat-radiating fins and a plurality of the abovementioned LED package structures stuck to the group of heat-radiating fins.

Below, embodiments are described in detail in cooperation with drawings to enable easily understood the technical contents, characteristics and accomplishments of the present invention.

### BRIEF DESCRIPTION OF THE DRAWINGS

FIG. 1 is a sectional view schematically showing a conventional LED package structure;

FIG. 2 is a perspective view schematically showing a LED package structure according to a first embodiment of the present invention;

FIG. 3 is an exploded view of part of components of the LED package structure according to the first embodiment of the present invention;

FIG. 4 is a top view schematically showing the LED package structure according to the first embodiment of the present invention;

FIG. 5 is a sectional view along Line A-A′ in FIG. 4;

FIG. 6 is a bottom view schematically showing the LED package structure according to the first embodiment of the present invention;

FIG. 7 is a side view schematically showing a LED module containing the LED package structures according to the first embodiment of the present invention;

FIG. 8 is a top view schematically showing a LED module containing the LED package structures according to the first embodiment of the present invention; and

FIG. 9 is a side view schematically showing a LED package structure according to a second embodiment of the present invention.

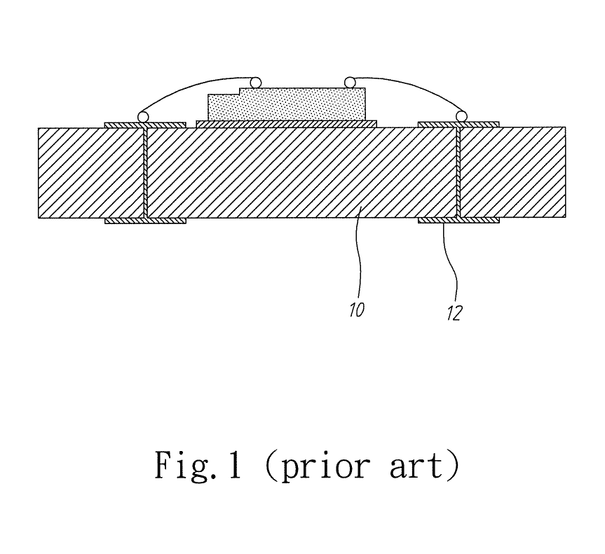

### DETAILED DESCRIPTION OF THE INVENTION

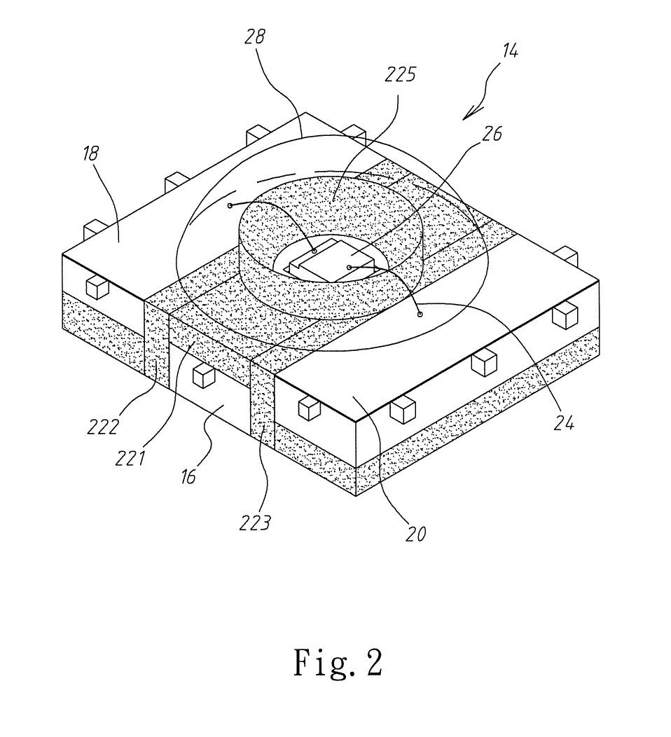

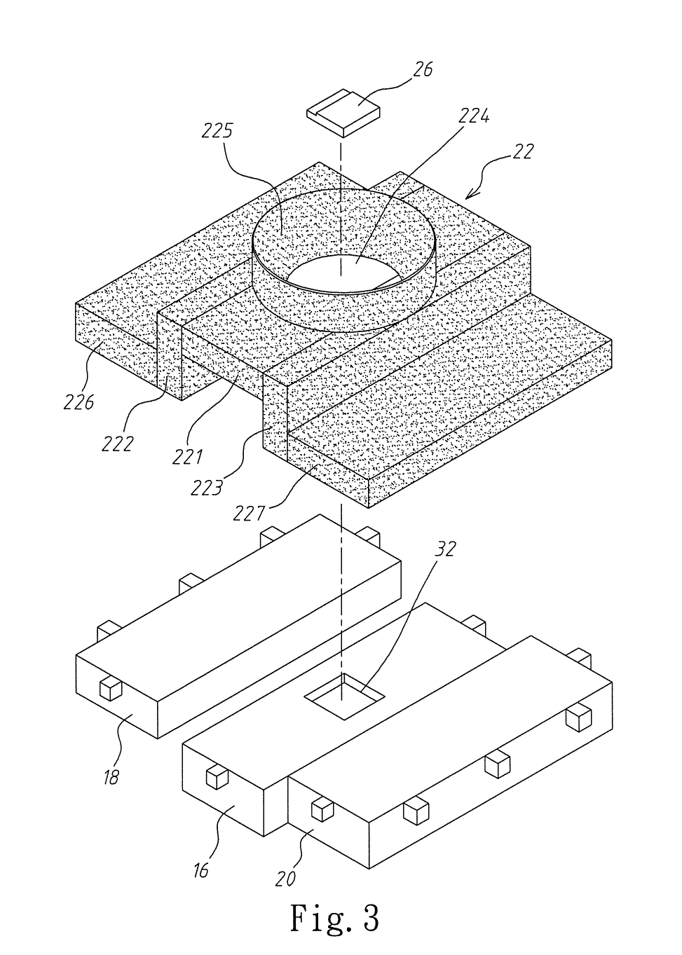

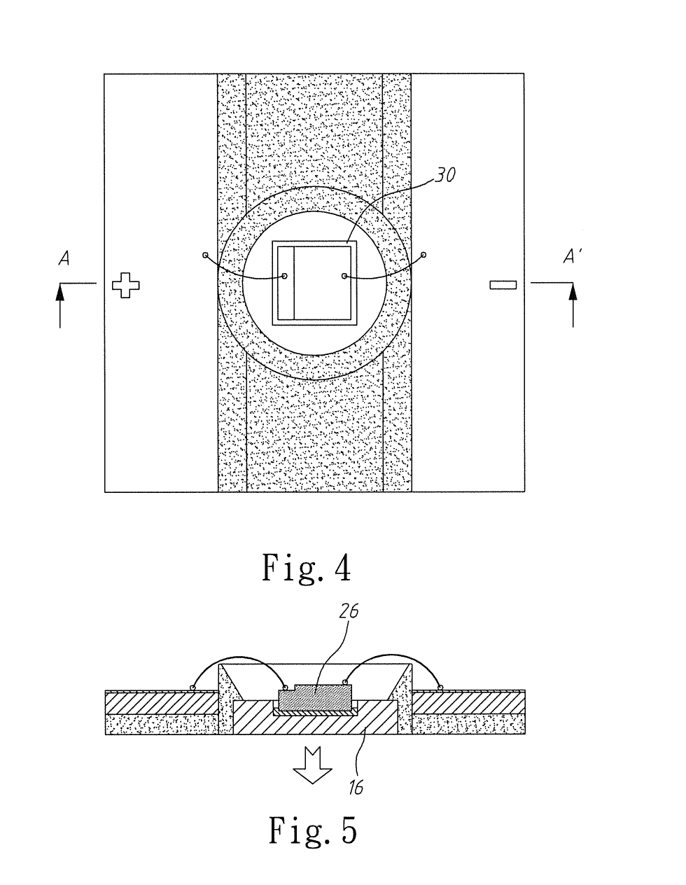

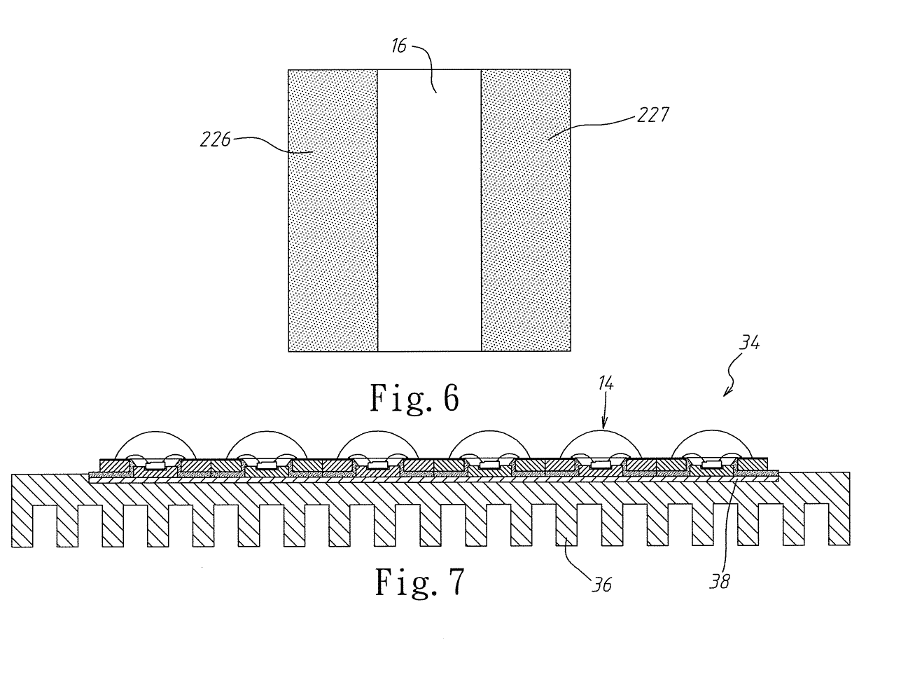

Refer to FIGS. 2-6 respectively a perspective view, an exploded view of part of components, a top view, a sectional view along Line A-A′, and a bottom view of a LED package structure according to a first embodiment of the present invention.

The LED package structure 14 of the present invention comprises a metallic chip-carrying lead frame 16, a metallic anode lead frame 18 and a metallic cathode lead frame 20, a forming resin 22 and a plurality of leads 24. At least one LED chip 26 is stuck to the metallic chip-carrying lead frame 16. The metallic anode lead frame 18 and the metallic cathode lead frame 20 are respectively arranged at two sides of the metallic chip-carrying lead frame 16.

The forming resin 22 is a thermosetting epoxy fabricated into a one-piece component with an advanced and precision press-molding technology of semiconductor package. The forming resin 22 includes a top member 221, a first sidewall 222, and a second sidewall 223. The top member 221 is arranged on the metallic chip-carrying lead frame 16 and has an opening 224 to reveal the LED chip 26. A reflective wall 225 is formed along the opening 224. The inner surface of the reflective wall 225 is an inclined surface coated with a reflective film. The first sidewall 222 is arranged between the metallic chip-carrying lead frame 16 and the metallic anode lead frame 18 to join the metallic chip-carrying lead frame 16 and the metallic anode lead frame 18. The second sidewall 223 is arranged between the metallic chip-carrying lead frame 16 and the metallic cathode lead frame 20 to join the metallic chip-carrying lead frame 16 and the metallic cathode lead frame 20.

The bottoms of the first sidewall 222 and the second sidewall 223 respectively extend outward to form insulating bottom plates 226 and 227 to electrically isolate the system circuit board or heat-radiating plate that is to be attached to the bottom of the LED package structure 14.

The metallic chip-carrying lead frame 16, metallic anode lead frame 18 and metallic cathode lead frame 20 are made of copper or Alloy 42. Alloy 42 has a thermal expansion coefficient of 4.4 ppm/c°, which is close to the thermal expansion coefficient of the substrate (made of sapphire Al₂O₃) of the LED chip. Therefore, temperature variation will not cause thermal stress therebetween. Further, Alloy 42 has an appropriate thermal conductivity (27 W/mK).

The metallic chip-carrying lead frame 16, metallic anode lead frame 18, metallic cathode lead frame 20 and forming resin 22 cooperate to form a novel high-thermal conductivity metallic baseplate structure. When the substrate of the LED chip is made of silicon or copper, the metallic chip-carrying lead frame 16, metallic anode lead frame 18 and metallic cathode lead frame 20 should adopt another metal as the material thereof to meet the requirements in thermal conduction and thermal expansion.

In one embodiment, a high-thermal conductivity powder is added to the thermosetting epoxy to increase the thermal conduction performance thereof. For example, a filler, which is made of a powder of aluminum nitride (having a thermal conductivity of 240 W/mK) or aluminum (having a thermal conductivity of 260 W/mK), increases the thermal conductivity of the forming resin 22, which is originally made of the thermosetting epoxy (having a thermal conductivity of only 0.2 W/mK), to 2 W/mK. The epoxy can endure a temperature of as high as 400° C. and will not be deteriorated by high temperature caused by a high-power LED.

The leads 24 electrically connect the LED chip 26 with the metallic anode lead frame 18 and the metallic cathode lead frame 20. The LED package structure of the present invention further comprises a lens 28 hooding the LED chip 26 and the leads 24. The lens 28 is made of a transparent silicone resin and fabricated in a secondary molding process. The silicone resin is preferred to have a transmittance of 99%, a refractivity of 1.6 and a semi-spherical shape, whereby to achieve the best focusing effect.

The LED package structure of the present invention further comprises a soft thermal conduction resin 30, which is an epoxy binder containing silver powder. The soft thermal conduction resin 30 is arranged between the LED chip 26 and the metallic chip-carrying lead frame 16, sticking the LED chip 26 to the metallic chip-carrying lead frame 16. In one embodiment, the metallic chip-carrying lead frame 16 has a basin 32 where the soft thermal conduction resin 30 is filled. The epoxy binder containing silver powder has a thermal conductivity of as high as 30 W/mK. Thus, it can reduce the thermal resistance between the LED chip and the copper baseplate.

When a high-power LED operates, temperature rising and thermal stress/strain are inevitable. The abovementioned factors must be taken into consideration lest the high-power LED be deficient in reliability. The sapphire (Al₂O₃) substrate of the LED chip has a thermal expansion coefficient of 6 ppm/c°. Copper has a thermal expansion coefficient of 16 ppm/c°. Temperature variation causes different expansions in the chip and the metallic chip-carrying lead frame 16 and generates thermal stress therebetween. Thus, stress-induced crack may occur in the LED chip. Therefore, the soft epoxy binder is applied between the LED chip 26 and the metallic chip-carrying lead frame 16 to relax the thermal stress therebetween. Further, the metallic chip-carrying lead frame 16 is etched or stamped to have a basin 32 to receive the soft binder.

Refer to FIG. 5. The metallic chip-carrying lead frame 16 is used as a non-electric thermal-conduction component. In addition to carrying the LED chip 26, the metallic chip-carrying lead frame 16 also functions to transfer the heat generated by the LED chip 26 downward. Therefore, the metallic chip-carrying lead frame 16 needs a greater area to benefit thermal conduction. In one embodiment, the metallic chip-carrying lead frame 16 is made of copper. Copper is superior in thermal conduction and mechanical properties. Copper also has a fine shielding performance. Therefore, copper can be used to construct an optimized vertical thermal path having a greater area and having a thickness of only 0.20 mm or less. The cupric chip-carrying lead frame 16 may achieve a thermal resistance of as low as 1° C./W and is suitable to the future 5-10 W high-power LED. The ordinary ceramic substrate has a thermal resistance of 6° C./W. The cupric chip-carrying lead frame 16 of the present invention only has one-sixth thermal resistance of the ordinary ceramic substrate and thus outperforms the ordinary ceramic substrate in thermal conduction.

In the present invention, a precision press-molding technology is used to fabricate a novel high-thermal conduction baseplate structure, wherein a metallic chip-carrying lead frame 16 is constructed to function as a thermal path, and wherein a metallic anode lead frame 18 and a metallic cathode lead frame 20 are constructed to function as electric paths, and wherein a reflective wall 225 is constructed to function as an optical path. The abovementioned paths are respectively arranged in the left, right, top and bottom of the substrate in a split way. The first sidewall 222, second sidewall 223, reflective wall 225, insulating bottom plates 226 and 227 of the forming resin 22 respectively have the following functions:
1. The first sidewall 222 and second sidewall 223 electrically isolate the metallic chip-carrying lead frame 16 from the metallic anode lead frame 18 and metallic cathode lead frame 20 to implement electric paths.
2. The reflective wall 225 is an inclined surface able to redirect the light emitted by the LED chip 26 to the front side exactly and concentrate the light. The reflective wall 225 is a smooth surface coated with a silver layer or an optical film, which functions as a reflective film (having a reflectivity of 98%) to redirect light and increase the intensity of light. The annular reflective wall 225 functions as a focusing cup to converge light to within a range of below 90 degrees.
3. The insulating bottom plates 226 and 227 make the bottom of the entire structure free of any electrode and enable the bottom to be directly joined to a heat-radiating plate or a circuit board, whereby is formed a superior thermal-conduction path.

The conventional electronic components are electrically connected with the system circuit board via the bottom thereof. In the present invention, the leads 24 electrically connects the LED chip 26 to the metallic anode lead frame 18 and metallic cathode lead frame 20 via the top of the LED package structure 14. Further, the bottom of the LED package structure 14 of the present invention is neutral and has none electrode. Therefore, the bottom of the LED package structure 14 can be directly joined to a heat-radiating plate to achieve high-thermal conduction performance. As the LED package structure 14 is electrically connected to the circuit via the upper side, the electric conduction path and the thermal conduction path are arranged in a split way in the present invention.

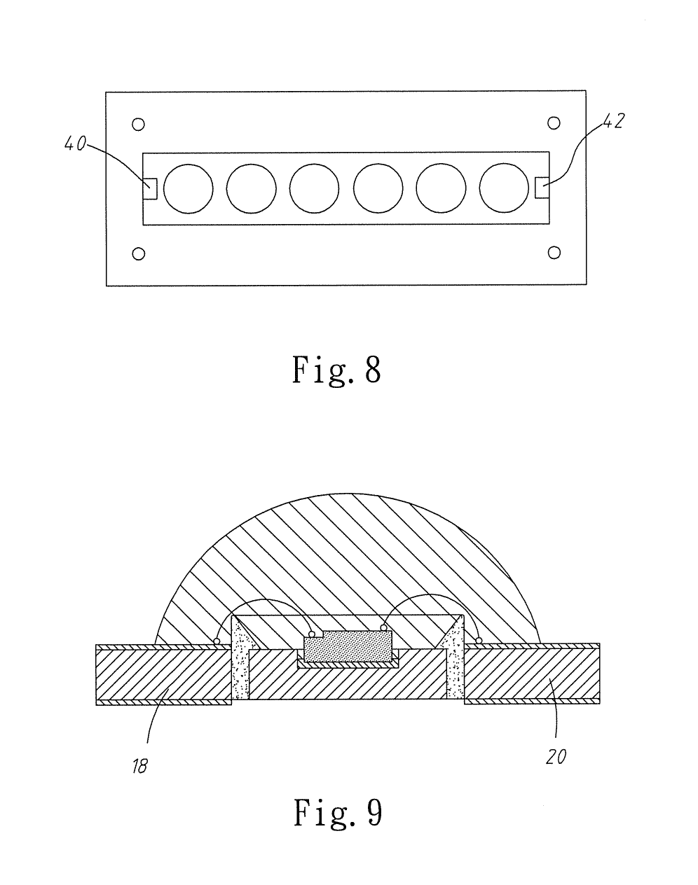

Refer to FIG. 7 and FIG. 8 respectively a side view and a top view of a LED module containing the LED package structures according to the first embodiment of the present invention. The LED module 34 comprises a group of heat-radiating fins 36, a thermal-conduction binder layer 38, and a plurality of the abovementioned LED package structures 14 bound by the thermal-conduction binder layer 38. The LED package structures 14 are connected in series or parallel. The LED module 34 has an anode contact 40 and a cathode contact 42 respectively at two ends of the upper side thereof to connect with the system circuit. Thus is realized the novel concept of the present invention: electricity and heat are respectively conducted via the upper path and the lower path. Besides, the heat-radiating fins 36 of the LED module 34 can be directly fixed to the housing of a lamp or an illumination system.

Refer to FIG. 9 a sectional view of a LED package structure according to a second embodiment of the present invention. In the second embodiment, none insulating bottom plate 226 or 227 is arranged below the metallic anode lead frame 18 or the metallic cathode lead frame 20, whereby to provide flexibility in connecting with the circuit board.

The embodiments described above are only to exemplify the present invention but not to limit the scope of the present invention. Any equivalent modification or variation according to the spirit of the present invention is to be also included within the scope of the present invention.

What is claimed is:

1. A light emitting diode package structure comprising
a metallic chip-carrying lead frame where at least one light emitting diode (LED) chip is stuck;
a metallic anode lead frame and a metallic cathode lead frame respectively arranged at two sides of said metallic chip-carrying lead frame;
a forming resin including
a top member arranged on said metallic chip-carrying lead frame and having an opening to reveal said LED chip, wherein a reflective wall is formed along said opening;
a first sidewall arranged between said metallic chip-carrying lead frame and said metallic anode lead frame to join said metallic chip-carrying lead frame and said metallic anode lead frame; and
a second sidewall arranged between said metallic chip-carrying lead frame and said metallic cathode lead frame to join said metallic chip-carrying lead frame and said metallic cathode lead frame; and
a plurality of leads electrically connecting said LED chip with said metallic anode lead frame and said metallic cathode lead frame.

2. The light emitting diode package structure according to claim 1, wherein an inner side of said reflective wall is an inclined surface.

3. The light emitting diode package structure according to claim 2, wherein said inclined surface is coated with a reflective film.

4. The light emitting diode package structure according to claim 1 further comprising a lens hooding said LED chip and said leads.

5. The light emitting diode package structure according to claim 1, wherein two insulating bottom plates are respectively formed below said metallic anode lead frame and said metallic cathode lead frame.

6. The light emitting diode package structure according to claim 5, wherein said insulating bottom plates and said forming resin are fabricated into a one-piece component.

7. The light emitting diode package structure according to claim 5, wherein said insulating bottom plates and said forming resin are made of a thermosetting epoxy.

8. The light emitting diode package structure according to claim 7, wherein said thermosetting epoxy contains a high-thermal conduction powder.

9. The light emitting diode package structure according to claim 1 further comprising a soft thermal conduction resin arranged between said LED chip and said metallic chip-carrying lead frame in order to stick said LED chip to said metallic chip-carrying lead frame.

10. The light emitting diode package structure according to claim 9, wherein said metallic chip-carrying lead frame is made of copper, and said soft thermal conduction resin is a soft epoxy thermal conduction resin.

11. The light emitting diode package structure according to claim 9, wherein said metallic chip-carrying lead frame has a basin to receive said soft thermal conduction resin.

12. The light emitting diode package structure according to claim 1, wherein said forming resin is made of a thermosetting epoxy.

13. The light emitting diode package structure according to claim 12, wherein said thermosetting epoxy contains a high-thermal conduction powder.

14. The light emitting diode package structure according to claim 1, wherein said metallic chip-carrying lead frame, said metallic anode lead frame and said metallic cathode lead frame are made of copper.

15. The light emitting diode package structure according to claim 5, which is joined to a heat-radiating plate or a ground line.

16. A light emitting diode module comprising
a group of heat-radiating fins; and
a plurality of light emitting diode package structures stuck to said group of heat-radiating fins and each including
a metallic chip-carrying lead frame where at least one light emitting diode (LED) chip is stuck;
a metallic anode lead frame and a metallic cathode lead frame respectively arranged at two sides of said metallic chip-carrying lead frame;
a forming resin further comprising
a top member arranged on said metallic chip-carrying lead frame and having an opening to reveal said LED chip, wherein a reflective wall is formed along said opening;
a first sidewall arranged between said metallic chip-carrying lead frame and said metallic anode lead frame to join said metallic chip-carrying lead frame and said metallic anode lead frame; and
a second sidewall arranged between said metallic chip-carrying lead frame and said metallic cathode lead frame to join said metallic chip-carrying lead frame and said metallic cathode lead frame; and
a plurality of leads electrically connecting said LED chip with said metallic anode lead frame and said metallic cathode lead frame.

17. The light emitting diode module according to claim 16, wherein an inner side of said reflective wall is an inclined surface.

18. The light emitting diode module according to claim 17, wherein said inclined surface is coated with a reflective film.

19. The light emitting diode module according to claim 16 further comprising a lens hooding said LED chip and said leads.

20. The light emitting diode module according to claim 16, wherein two insulating bottom plates are respectively formed below said metallic anode lead frame and said metallic cathode lead frame.

21. The light emitting diode module according to claim 20, wherein said insulating bottom plates and said forming resin are fabricated into a one-piece component.

22. The light emitting diode module according to claim 20, wherein said insulating bottom plates and said forming resin are made of a thermosetting epoxy.

23. The light emitting diode module according to claim 22, wherein said thermosetting epoxy contains a high-thermal conduction powder.

24. The light emitting diode module according to claim 16 further comprising a soft thermal conduction resin arranged between said LED chip and said metallic chip-carrying lead frame in order to stick said LED chip to said metallic chip-carrying lead frame.

25. The light emitting diode module according to claim 24, wherein said metallic chip-carrying lead frame is made of copper, and said soft thermal conduction resin is a soft epoxy thermal conduction resin.

26. The light emitting diode module according to claim 24, wherein said metallic chip-carrying lead frame has a basin to receive said soft thermal conduction resin.

27. The light emitting diode module according to claim 16, wherein said forming resin is made of a thermosetting epoxy.

28. The light emitting diode module according to claim 27, wherein said thermosetting epoxy contains a high-thermal conduction powder.

29. The light emitting diode module according to claim 16, wherein said metallic chip-carrying lead frame, said metallic anode lead frame and said metallic cathode lead frame are made of copper.

30. The light emitting diode module according to claim 16, wherein a thermal-conduction binder layer is arranged between said group of heat-radiating fins and said LED package structures.
